(19) United States
(12) Patent Application Publication
(10) Pub. No.: US 2026/0171816 A1
(43) Pub. Date: Jun. 18, 2026

(54) BATTERY MANAGEMENT SYSTEM (BMS) ANALOG FRONT-END (AFE) AND ACTIVE CELL BALANCING ARCHITECTURE

(71) Applicant: Microchip Technology Incorporated, Chandler, AZ (US)

(72) Inventor: Hoi Keung Tang, Tokyo (JP)

(21) Appl. No.: 19/401,623

(22) Filed: Nov. 26, 2025

Related U.S. Application Data
(60) Provisional application No. 63/733,531, filed on Dec. 13, 2024.

(51) Int. Cl. H02J 7/00; G01R 31/3842; H01M 10/42; H01M 10/48

(52) U.S. Cl. CPC H02J 7/56; G01R 31/3842; H01M 10/425; H01M 10/482; H01M 10/486; H02J 7/927; H01M 2010/4271; H01M 2010/4278; H02J 2207/20

(57) ABSTRACT

A centralized control unit for actively balancing a multi-cell battery pack is provided. The centralized control unit may include an analog-to-digital converter (ADC) to monitor and digitize voltage readings of the battery cells in the multi-cell battery pack, a microcontroller unit (MCU) to process the digitized voltage readings from the ADC, analyze a state of the battery cells, and execute one or more balancing algorithms, and a DC-DC converter to enable redistribution of energy to maintain balance across the battery cells.

### CROSS-REFERENCE TO RELATED APPLICATION

The present application claims priority from U.S. Provisional Patent Application No. 63/733,531 filed on Dec. 13, 2024, which is incorporated herein by reference in its entirety.

### TECHNICAL FIELD

The present disclosure relates generally to a battery management system (BMS), and more specifically to a BMS with an active cell balancing configuration.

### SUMMARY

According to an aspect of one or more examples, there is provided a centralized control unit for actively balancing a multi-cell battery pack. The centralized control unit may include an analog-to-digital converter (ADC) to monitor and digitize voltage readings of the battery cells in the multi-cell battery pack, a microcontroller unit (MCU) to process the digitized voltage readings from the ADC, analyze a state of the battery cells, and execute one or more balancing algorithms, and a DC-DC converter to enable redistribution of energy to maintain balance across the battery cells. The ADC may monitor and digitize current and temperature readings of the battery cells in the multi-cell battery pack and transmit the readings to the MCU for processing. The MCU may analyze the readings from the ADC to determine if any battery cells are outside a voltage range or if there is an imbalance in a state of charge between battery cells, and if an imbalance is detected, activate appropriate isolated gate drive circuits to connect an overcharged or undercharged battery cell to the DC-DC converter. The DC-DC converter may cause energy to be transferred from a higher voltage battery cell to a lower voltage battery cell and cause energy to be taken from a higher voltage battery cell to lower its voltage to match a lower voltage battery cell. The DC-DC converter may enable redistribution of energy by enabling energy transfer between one or more battery cells of the plurality of battery cells and a centralized energy storage or redistribution point. The centralized energy storage or redistribution point may be a capacitor, an inductor, or a centralized battery bank. The centralized control unit may include a communication interface to provide a communication link to communicate system status and report diagnostic information in real time for monitoring and maintenance. The diagnostic information may include battery cell voltages, state of charge, and thermal conditions.

According to an aspect of one or more examples, there is provided a battery management system for actively balancing a multi-cell battery pack. The battery management system may include a plurality of battery cells arranged in a series configuration and to store and discharge energy, a plurality of isolated gate drive circuits respectively coupled to the plurality of battery cells and to selectively activate switches that facilitate energy transfer, a centralized control unit including an analog-to-digital converter (ADC) to monitor and digitize voltage readings of the battery cells in the multi-cell battery pack, a microcontroller unit (MCU) to process the digitized voltage readings from the ADC, analyze one or more states of the plurality of battery cells, and execute one or more balancing algorithms, a DC-DC converter to enable redistribution of energy to maintain balance across the plurality of battery cells, and a pulse-width modulation (PWM) driver to generate control signals for the DC-DC converter to adjust energy transfer rates. The isolated gate drive circuits may electrically isolate the battery cells and the centralized control unit. The switches that facilitate energy transfer may be MOSFETs or IGBTs. The MCU may analyze the voltage readings from the ADC to determine if any battery cells of the plurality of battery cells are outside a voltage range or if there is an imbalance in a state of charge between battery cells, and in response to determining an imbalance in the state of charge between battery cells, or that one or more battery cells of the plurality of battery cells is outside the voltage range, activate one or more isolated gate drive circuits to connect an overcharged or undercharged battery cell to the DC-DC converter according to the one or more balancing algorithms. The DC-DC converter may perform a step-up function to transfer energy from a higher voltage battery cell of the plurality of battery cells to a lower voltage battery cell of the plurality of battery cells, and a step-down function to take energy from a higher voltage battery cell of the plurality of battery cells to lower its voltage to match a lower voltage battery cell of the plurality of battery cells. The battery management system may include a communication interface to provide a communication link to communicate system status and report diagnostic information in real time for monitoring and maintenance. The diagnostic information may include one or more of battery cell voltages, state of charge, and thermal conditions. The DC-DC converter may enable redistribution of energy by enabling energy transfer between one or more battery cells of the plurality of battery cells and a centralized energy storage or redistribution point.

According to an aspect of one or more examples, there is provided a method for actively balancing a multi-cell battery pack. The method may include monitoring and digitizing voltage readings of battery cells in the multi-cell battery pack using an analog-to-digital converter (ADC), processing the digitized voltage readings from the ADC, analyzing one or more states of the plurality of battery cells, and executing one or more balancing algorithms using a microcontroller unit (MCU), enabling energy redistribution to maintain balance across all battery cells using a DC-DC converter. The method may include generating control signals for the DC-DC converter to adjust one or more energy transfer rates using a pulse-width modulation (PWM) driver. The method may include analyzing the voltage readings from the ADC to determine if any battery cells of the plurality of battery cells are outside a voltage range or if there is an imbalance in a state of charge between battery cells, and in response to determining an imbalance in the state of charge between battery cells, or that one or more battery cells of the plurality of battery cells is outside the voltage range, activating one or more isolated gate drive circuits to connect an overcharged or undercharged battery cell to the DC-DC converter according to the one or more balancing algorithms. The energy redistribution may include enabling energy transfer between one or more battery cells of the plurality of battery cells and a centralized energy storage or redistribution point. The centralized energy storage or redistribution point may be a capacitor, an inductor, or a centralized battery bank. The method may include performing a step-up function to transfer energy from a higher voltage battery cell of the plurality of battery cells to a lower voltage battery cell of the plurality of battery cells, and performing a step-down function to take energy from a higher voltage battery cell of the plurality of battery cells to lower its voltage to match a lower voltage battery cell of the plurality of battery cells. The method may include providing a communication link to external systems using a communication interface to communicate system status and report diagnostic information in real time for monitoring and maintenance.

### BRIEF DESCRIPTION OF DRAWINGS

FIG. 1 shows a schematic of a battery management system (BMS) with an active cell balancing configuration according to the prior art.

FIG. 2 shows a schematic of a BMS with an active cell balancing configuration that uses isolated gate drive circuits and centralized control according to one or more examples.

FIG. 3 shows a centralized control unit for actively balancing a multi-cell battery pack according to one or more examples.

FIG. 4 shows a method for actively balancing a multi-cell battery pack according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

In recent years, advancements in energy storage technology have led to the development of battery systems with increasingly larger capacities. These high-capacity batteries are widely used in applications such as electric vehicles (EVs), renewable energy storage, consumer electronics, and industrial systems. However, as battery packs become larger and more complex, effective battery management systems (BMSs) are important to ensure safety, reliability, and performance.

One of the challenges in battery systems is maintaining the balance of individual cells within the pack. Variations in cell capacities, internal resistances, and states of charge (SOC) can cause cells to become imbalanced over time. If left unaddressed, imbalances can lead to reduced energy efficiency, diminished battery life, and even safety risks such as thermal runaway.

Traditional passive cell balancing techniques dissipate excess energy from higher-voltage cells as heat, using resistors to equalize the voltages across the cells. While this approach is simple and cost-effective for small-scale battery systems, it is increasingly inadequate for larger capacity battery packs. Passive balancing is inherently slow, and the heat dissipation becomes difficult to manage as the system scales. This limitation highlights the need for more efficient and scalable balancing methods.

Active cell balancing has emerged as a preferred alternative to address these limitations. By actively redistributing energy between cells, active balancing improves energy efficiency, maximizes battery capacity utilization, and reduces heat generation. Despite these advantages, current active cell balancing solutions are often associated with higher costs, greater design complexity, and increased power consumption, creating barriers to widespread adoption. To address this gap, there is a growing demand for innovative active cell balancing solutions that offer lower cost to make active balancing accessible for a wider range of applications, lower power consumption to improve system efficiency, and simpler designs to facilitate integration into battery management systems.

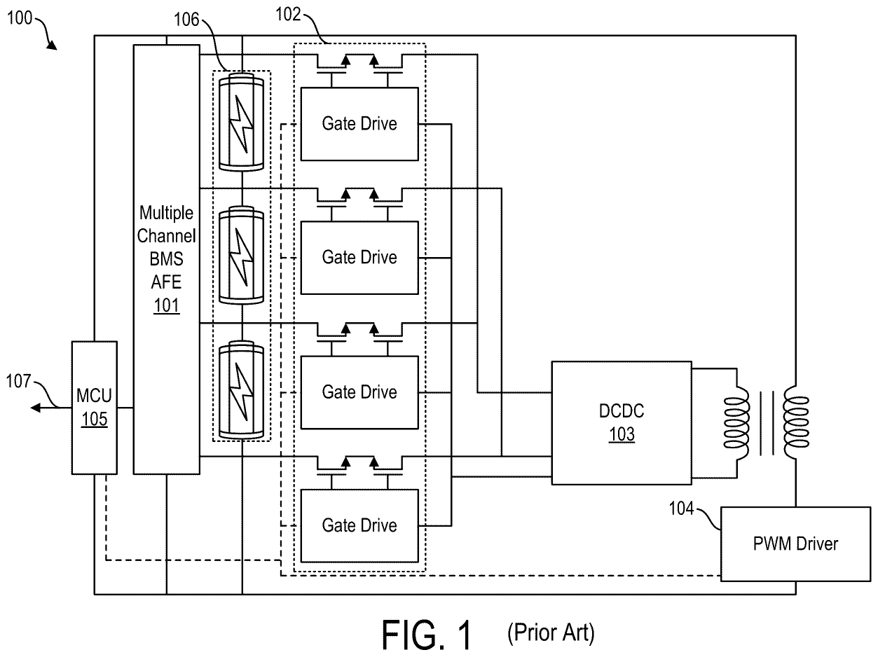

FIG. 1 shows a schematic of a battery management system (BMS) 100 with an active cell balancing configuration according to the prior art. As shown in FIG. 1, the BMS 100 may include a multiple channel BMS analog front-end (AFE) 101, gate drive circuits 102, a DC-DC converter 103, a pulse width modulation (PWM) driver 104, a microcontroller unit (MCU) 105, battery cells 106, and a communication interface 107.

The multiple channel BMS analog front-end (AFE) 101 may be responsible for monitoring the individual parameters of each battery cell 106, such as voltage, current, and temperature. The multiple channel BMS AFE 101 may serve as an interface between the battery cells 106 and the MCU 105, digitizing analog signals from the cells and transmitting this data to the MCU 105 for processing. The battery cells 106 may be arranged in a series or parallel configuration. Each cell may exhibit variations in capacity and state of charge (SOC), which may be corrected through active balancing. The BMS 100 may ensure that the cells 106 remain within an acceptable voltage range, improving overall pack performance and longevity. Each gate drive 102 may be paired with a corresponding battery cell 106. Gate drives 102 may be responsible for controlling the switches (e.g., MOSFETs or IGBTs) that facilitate energy transfer. The gate drives 102 may operate under the control of the MCU 105, allowing selective activation of the balancing circuitry (e.g., the DC-DC converter 103) for each cell 106. The DC-DC converter 103 may enable efficient energy transfer between cells 106 or between a cell 106 and a centralized energy storage or redistribution point (e.g., a capacitor, an inductor, a centralized battery bank, without limitation). Unlike passive balancing, which dissipates excess energy as heat, the DC-DC converter 103 may redistribute energy to maintain balance across the cells 106 with minimal energy loss. The PWM driver 104 may generate control signals for the DC-DC converter 103, adjusting the energy transfer rates dynamically. The PWM driver 104 may operate in conjunction with the MCU 105 to ensure precise energy redistribution based on real-time cell voltage and SOC measurements. The MCU 105 may serve as the central control unit for the system. The MCU 105 may process the digitized data received from the multiple channel BMS AFE 101, analyze the state of each cell 106, and execute balancing algorithms. The MCU 105 may communicate with the gate drives 102 and the PWM driver 104 to initiate and control the balancing process. Additionally, the MCU 105 may provide system-level control and diagnostic capabilities via an external communication interface 107, enabling monitoring and configuration of the BMS 100. The communication interface 107 may allow the BMS 100 to interact with external systems, such as vehicle controllers, energy management systems, or user interfaces. The communication interface 107 may facilitate data exchange, including battery health, state of charge, and other diagnostic information.

During operation, the multiple channel BMS AFE 101 may continuously monitor the voltage, current, and temperature of the cells 106 in the battery pack. This data may be transmitted to the MCU 105 for processing. The MCU 105 may analyze the data to determine if any cells 106 are outside the desired voltage range or if there is a significant imbalance in SOC between cells 106. If an imbalance is detected, the MCU 105 may activate the appropriate gate drive 102 to connect the overcharged or undercharged cell 106 to the DC-DC converter 103. The PWM driver 104 may regulate the energy transfer rate, ensuring efficient redistribution of energy to achieve balance. Energy may be transferred from cells with higher voltage to those with lower voltage or to a centralized storage point. The DC-DC converter 103 may reduce energy loss during this process, improving system efficiency compared to passive methods. The MCU 105 may communicate system status and diagnostic information via the communication interface 107, providing real-time insights into the battery pack's condition.

While the multiple channel BMS AFE 101 may enable precise monitoring and control of each individual cell 106, the increased cost, complexity, power consumption and potential reliability issues can outweigh the benefits in certain applications. Additionally, the gate drives 102 may be powered by the battery cells 106, and draw current to operate the switching mechanisms (e.g., MOSFETs) that regulate energy transfer. The gate drives 102 may require a small amount of power to activate and deactivate the switches for energy balancing operations. This power draw may come directly from the connected battery cells 106. Drawing current from the battery cells 106 to power the gate drives 102 may introduce several potential issues including battery cell imbalance, reduction in cell capacity, increased wear and tear, thermal effects, reduced efficiency, and design complexity.

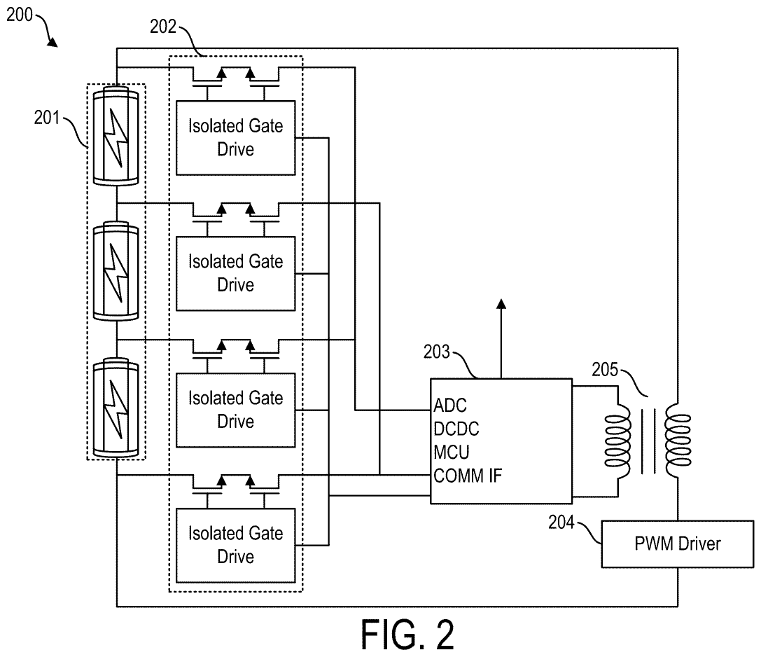

FIG. 2 shows a schematic of a BMS 200 with an active cell balancing configuration that uses isolated gate drive circuits and centralized control according to one or more examples. As shown in FIG. 2, the BMS 200 may include battery cells 201, isolated gate drive circuits 202, a centralized control unit 203, and a PWM driver 204. The design may improve scalability, efficiency, and performance in balancing battery cells 201 within a multi-cell battery pack. The system may enable efficient redistribution of energy between cells 201, improving performance and safety in high-capacity battery systems, such as those used in electric vehicles, energy storage, and portable devices.

The BMS 200 may manage multiple battery cells 201 connected in a series configuration. The battery cells 201 may be monitored and actively balanced to maintain uniform voltage and SOC, preventing imbalances that can degrade battery performance or safety. Each battery cell 201 may be connected to an isolated gate drive circuit 202 that controls a power switch (e.g., a MOSFET or IGBT). The isolated gate drives 202 may enable selective energy transfer between individual battery cells 201 and the balancing circuitry, which may include a DC-DC flyback converter controlled by the centralized control unit 203. The isolation provided by the isolated gate drives 202 may ensure that high-voltage cells can be controlled independently without cross-interference, improving safety and system modularity.

The centralized control unit 203 may include several sub-functions, including an analog-to-digital converter (ADC), a DC-DC converter (DCDC), a microcontroller unit (MCU), and a communication interface (COMM IF). The ADC may monitor and digitize the voltage, current, and temperature readings of the battery cells 201 for processing by the MCU. The DC-DC converter may facilitate energy transfer within the system by isolating and regulating voltage levels during the balancing process. The DC-DC converter may be a flyback converter that uses a transformer 205 to store energy magnetically on a primary side and transfer it to a secondary side, enabling precise and electrically isolated redistribution of energy between overcharged and undercharged cells. For example, the primary side of the transformer may store energy from the battery cells 201 and transfer it to the secondary side. The secondary side of the transformer may be coupled to the centralized control unit 203, including the DC-DC converter, and the DC-DC converter may include capacitors to store the transferred energy. The MCU may act as the central processing and control unit. The MCU may execute one or more balancing algorithms based on the ADC readings and determine which cells 201 to perform energy redistribution. The communication interface may provide a communication link between the BMS 200 and external systems, such as monitoring interfaces or vehicle control units. The communication interface may enable real-time monitoring and diagnostics of the battery system. The PWM driver 204 may generate pulse-width modulation (PWM) signals to control the DC-DC converter and energy transfer rates. The PWM driver 204 may dynamically adjust the duty cycle of the DC-DC converter's primary switch, working in conjunction with the MCU to ensure precise energy redistribution. The BMS 200 may also include pathways for transferring energy either between cells or through a centralized storage bus. The centralized storage bus may include a shared energy reservoir, including components such as a capacitor, an inductor, a centralized battery bank, without limitation. The DC-DC converter may facilitate energy transfer from a higher-voltage cell to a lower-voltage cell, or from the centralized storage bus to individual cells.

During operation, the single-channel ADC may continuously monitor the voltage of the battery cells 201 to detect imbalances. Additional parameters, such as temperature and current, may also be measured to ensure safe operating conditions. If the MCU detects a voltage or SOC imbalance among cells 201, it may activate the appropriate isolated gate drives 202 to initiate the balancing process. The one or more balancing algorithms may ensure energy is transferred efficiently to equalize cell voltages.

The PWM driver 204 may control the DC-DC converter to enable precise and electrically isolated energy transfer. The DC-DC converter may be a flyback converter that uses a transformer to store energy in its magnetic field during a primary switching phase and transfer this energy to its secondary side during a switching off phase. The DC-DC converter may regulate energy transfer by adjusting the PWM duty cycle, allowing energy to be redistributed from overcharged cells to undercharged cells. This energy may be transferred through a centralized storage bus or through a central balancing bus, which acts as a shared electrical pathway connecting the DC-DC converter to the battery cells 201.

The isolated gate drives 202 may further ensure electrical isolation between the battery cells 201, which may improve safety and reduce the risk of cross-cell interference. This isolation may also enable modularity, allowing the system to scale for different battery pack sizes and configurations. The communication interface may communicate the system status to external devices, such as battery management software or vehicle controllers. Diagnostic information, including cell voltages, SOC, and thermal conditions, may be reported in real time for monitoring and maintenance.

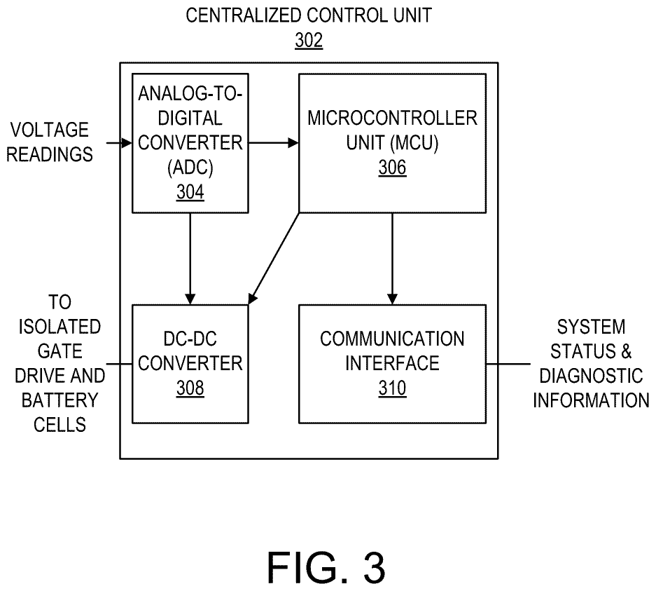

FIG. 3 shows a centralized control unit 302 for actively balancing a multi-cell battery pack according to one or more examples. The centralized control unit 302 may correspond to the centralized control unit 203 in FIG. 2, and may include an analog-to-digital converter (ADC) 304, a microcontroller unit (MCU) 306, and DC-DC converter 308, and a communication interface 310. The ADC 304 may monitor and digitize voltage readings, as well as current and temperature readings, of a plurality of battery cells for processing by the MCU 306. The DC-DC converter 308 may facilitate energy transfer within the system by isolating and regulating voltage levels during the balancing process. The MCU 306 may execute one or more balancing algorithms based on the ADC readings and determine which battery cells to use for performing energy redistribution. The communication interface 310 may provide a communication link between the battery management system and external systems, such as monitoring interfaces or vehicle control units. The communication interface 310 may enable real-time monitoring and diagnostics of the battery system.

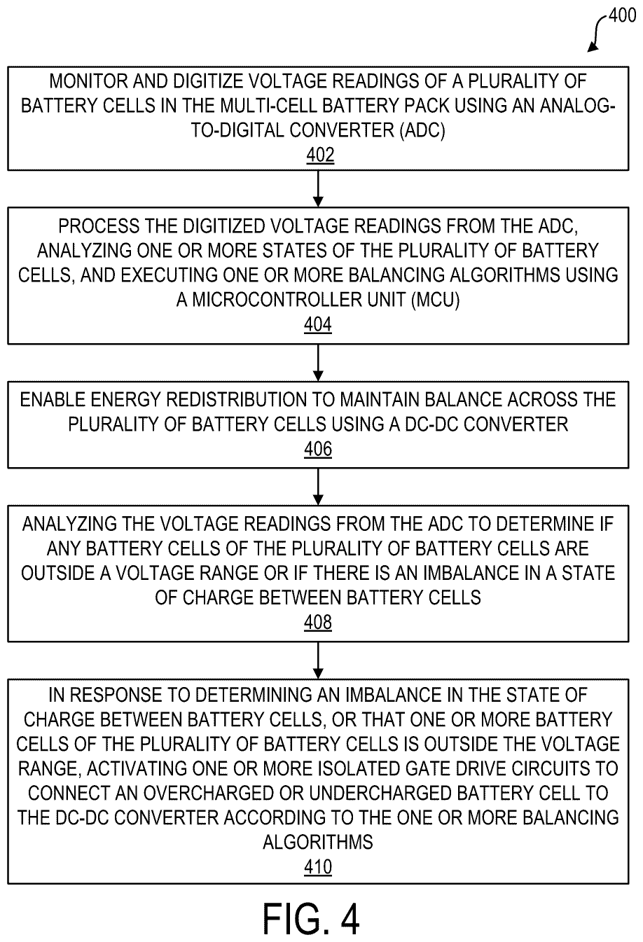

FIG. 4 shows a method 400 for actively balancing a multi-cell battery pack according to one or more examples. In operation 402, method 400 may monitor and digitize voltage readings of a plurality of battery cells in the multi-cell battery pack using an analog-to-digital converter (ADC). In operation 404, method 400 may process the digitized voltage readings from the ADC, analyze one or more states of the plurality of battery cells, and execute one or more balancing algorithms using a microcontroller unit (MCU). In operation 406, method 400 may enable energy redistribution to maintain balance across the plurality of battery cells using a DC-DC converter.

In operation 408, method 400 may analyze the voltage readings from the ADC to determine if any battery cells of the plurality of battery cells are outside a voltage range or if there is an imbalance in a state of charge between battery cells. In operation 408, in response to determining an imbalance in the state of charge between battery cells, or that one or more battery cells of the plurality of battery cells is outside the voltage range, method 400 may activate one or more isolated gate drive circuits to connect an overcharged or undercharged battery cell to the DC-DC converter according to the one or more balancing algorithms.

The energy redistribution of operation 406 may include enabling energy transfer between one or more battery cells of the plurality of battery cells and a centralized energy storage or redistribution point. The centralized energy storage or redistribution point may be a capacitor, an inductor, or a centralized battery bank. The method may include performing a step-up function to transfer energy from a higher voltage battery cell of the plurality of battery cells to a lower voltage battery cell of the plurality of battery cells, and performing a step-down function to take energy from a higher voltage battery cell of the plurality of battery cells to lower its voltage to match a lower voltage battery cell of the plurality of battery cells. The method may also include providing a communication link to external systems using a communication interface to communicate system status and report diagnostic information in real time for monitoring and maintenance.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A centralized control unit for actively balancing a multi-cell battery pack, the centralized control unit comprising:
an analog-to-digital converter (ADC) to monitor and digitize voltage readings of a plurality of battery cells in the multi-cell battery pack;
a microcontroller unit (MCU) to process the digitized voltage readings from the ADC, analyze one or more states of the plurality of battery cells, and execute one or more balancing algorithms; and
a DC-DC converter to enable redistribution of energy to maintain balance across the plurality of battery cells.

2. The centralized control unit of claim 1, wherein the ADC is to monitor and digitize current and temperature readings of the plurality of battery cells and transmit the digitized current and temperature readings to the MCU for processing.

3. The centralized control unit of claim 1, wherein the MCU is to:
analyze the voltage readings from the ADC to determine if any battery cells of the plurality of battery cells are outside a voltage range or if there is an imbalance in a state of charge between battery cells, and
in response to determining an imbalance in the state of charge between battery cells, or that one or more battery cells of the plurality of battery cells is outside the voltage range, activate appropriate isolated gate drive circuits to connect an overcharged or undercharged battery cell to the DC-DC converter.

4. The centralized control unit of claim 1, wherein the DC-DC converter is to cause energy to be transferred from a higher voltage battery cell of the plurality of battery cells to a lower voltage battery cell of the plurality of battery cells, and cause energy to be taken from a higher voltage battery cell of the plurality of battery cells to lower its voltage to match a lower voltage battery cell of the plurality of battery cells.

5. The centralized control unit of claim 1, wherein the DC-DC converter is to enable redistribution of energy by enabling energy transfer between one or more battery cells of the plurality of battery cells and a centralized energy storage or redistribution point; and
wherein the centralized energy storage or redistribution point is a capacitor, an inductor, or a centralized battery bank.

6. The centralized control unit of claim 1, comprising a communication interface to provide a communication link to communicate system status and report diagnostic information in real time for monitoring and maintenance.

7. The centralized control unit of claim 6, wherein the diagnostic information includes one or more of battery cell voltages, state of charge, and thermal conditions.

8. A battery management system for actively balancing a multi-cell battery pack, the battery management system comprising:
a plurality of battery cells arranged in a series configuration to store and discharge energy;
a plurality of isolated gate drive circuits respectively coupled to the plurality of battery cells and to selectively activate switches that facilitate energy transfer;
a centralized control unit comprising:
an analog-to-digital converter (ADC) to monitor and digitize voltage readings of the plurality of battery cells;
a microcontroller unit (MCU) to process the digitized voltage readings from the single channel ADC, analyze one or more states of the plurality of battery cells, and execute one or more balancing algorithms; and
a DC-DC converter to enable redistribution of energy to maintain balance across the plurality of battery cells; and
a pulse-width modulation (PWM) driver to generate control signals for the DC-DC converter to adjust one or more energy transfer rates.

9. The battery management system of claim 8, wherein the isolated gate drive circuits are to electrically isolate the plurality of battery cells and the centralized control unit.

10. The battery management system of claim 8, wherein the MCU is to:
analyze the voltage readings from the ADC to determine if any battery cells of the plurality of battery cells are outside a voltage range or if there is an imbalance in a state of charge between battery cells; and
in response to determining an imbalance in the state of charge between battery cells, or that one or more battery cells of the plurality of battery cells is outside the voltage range, activate one or more isolated gate drive circuits to connect an overcharged or undercharged battery cell to the DC-DC converter according to the one or more balancing algorithms.

11. The battery management system of claim 8, wherein the DC-DC converter is to cause energy to be transferred from a higher voltage battery cell of the plurality of battery cells to a lower voltage battery cell of the plurality of battery cells, and cause energy to be taken from a higher voltage battery cell of the plurality of battery cells to lower its voltage to match a lower voltage battery cell of the plurality of battery cells.

12. The battery management system of claim 8, comprising a communication interface to provide a communication link to communicate system status and report diagnostic information in real time for monitoring and maintenance.

13. The battery management system of claim 12, wherein the diagnostic information includes one or more of battery cell voltages, state of charge, and thermal conditions.

14. The battery management system of claim 8, wherein the DC-DC converter is to enable redistribution of energy by enabling energy transfer between one or more battery cells of the plurality of battery cells and a centralized energy storage or redistribution point.

15. A method for actively balancing a multi-cell battery pack, comprising:
monitoring and digitizing voltage readings of a plurality of battery cells in the multi-cell battery pack using an analog-to-digital converter (ADC);
processing the digitized voltage readings from the ADC, analyzing one or more states of the plurality of battery cells, and executing one or more balancing algorithms using a microcontroller unit (MCU); and
enabling energy redistribution to maintain balance across the plurality of battery cells using a DC-DC converter.

16. The method of claim 15, comprising generating control signals for the DC-DC converter to adjust one or more energy transfer rates using a pulse-width modulation (PWM) driver.

17. The method of claim 15, comprising:
analyzing the voltage readings from the ADC to determine if any battery cells of the plurality of battery cells are outside a voltage range or if there is an imbalance in a state of charge between battery cells; and
in response to determining an imbalance in the state of charge between battery cells, or that one or more battery cells of the plurality of battery cells is outside the voltage range, activating one or more isolated gate drive circuits to connect an overcharged or undercharged battery cell to the DC-DC converter according to the one or more balancing algorithms.

18. The method of claim 15, wherein the energy redistribution comprises enabling energy transfer between one or more battery cells of the plurality of battery cells and a centralized energy storage or redistribution point; and
wherein the centralized energy storage or redistribution point is a capacitor, an inductor, or a centralized battery bank.

19. The method of claim 15, comprising:
causing energy to be transferred from a higher voltage battery cell of the plurality of battery cells to a lower voltage battery cell of the plurality of battery cells; and
causing energy to be taken from a higher voltage battery cell of the plurality of battery cells to lower its voltage to match a lower voltage battery cell of the plurality of battery cells.

20. The method of claim 15, comprising providing a communication link to external systems using a communication interface to communicate system status and report diagnostic information in real time for monitoring and maintenance.
